(19) United States
(12) Patent Application Publication
(10) Pub. No.: US 2025/0102231 A1
(43) Pub. Date: Mar. 27, 2025

(54) Heat Exchange Device

(71) Applicant: Cooler Master Co., Ltd., Taipei City (TW)

(72) Inventor: Pen-hung Liao, Taipei City (TW)

(21) Appl. No.: 18/892,400

(22) Filed: Sep. 22, 2024

(30) Foreign Application Priority Data
Sep. 22, 2023 (TW) 112210308

(51) Int. Cl. F28D 7/16

(52) U.S. Cl. CPC F28D 7/16

(57) ABSTRACT

A heat exchange device may include a fin stack, plurality of heat pipes, and thermally conductive substrate. The fins stack includes a plurality of fins defining a stacked direction. The plurality of heat pipes have a fin stack portion, transportation portion, and substrate portion. The transportation portion is between the fin stack portion and the substrate portion. The thermally conductive substrate includes a top surface and bottom surface. The fin stack portion is coupled to each plurality of fins and the substrate portion is coupled to the top surface. The bottom surface is configured to couple to at least one packaged integrated circuit. The transportation portion includes at least one bend defining a gap between the fin stack and the top surface. A direction of the stacked direction is along a plane of the top surface.

### RELATED APPLICATIONS

This US application claims the benefit of priority to Taiwan application no. 112210308, filed on Sep. 22, 2023, of which is incorporated herein by reference in its entirety.

### TECHNICAL FIELD

The present disclosure relates to heat-transfer components and assemblies, and more particularly, but not limited to, thermally conductive substrate assemblies.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling systems such as air-cooling systems and liquid cooling systems are used to efficiently dissipate the heat generated by the electronic device and, thereby ensure the standard operation of the electronic device.

In the case of air-cooling systems for packaged integrated circuits, heat is dissipated from an upper surface of a packaged integrated circuit via upper surface adherence of a heatsink or thermally conductive substrate to the packaged integrated circuit.

Generally, heat pipes and fin stacks are used in conjunction with thermally conductive substrates. For some heat exchange devices, the heat pipes are connected to the thermally conductive substrates on one end and connected to the fins stack on the other end. The connection of the thermally conductive substrate, the heat pipe and the fin stack may be along a same longitudinal axis. Decreasing a longitudinal axis footprint of heat exchange devices with efficient and effective heat dissipation and stable structural integrity continue to be a challenge.

### SUMMARY OF THE INVENTION

The present disclosure provides a heat exchange device with compact footprint and high thermal conductivity.

In some aspects, the techniques described herein relate to a heat exchange device, including a fin stack, a plurality of heat pipes, and a thermally conductive substrate. The fin stack includes a plurality of fins defining a stacked direction. The plurality of heat pipes have a fin stack portion, a transportation portion, and a substrate portion. The transportation portion is between the fin stack portion and the substrate portion. The thermally conductive substrate includes a top surface and a bottom surface. The fin stack portion is coupled to each plurality of fins and the substrate portion is coupled to the top surface. The bottom surface is configured to couple to at least one packaged integrated circuit. The transportation portion includes at least one bend defining a gap between the fin stack and the top surface. A direction of the stacked direction is along a plane of the top surface.

In some aspects, the techniques described herein relate to a heat exchange device, wherein the thermally conductive substrate further includes a median, a first portion, and a second portion. The median defines the first portion on one side and the second portion on an opposite neighboring side. The substrate portion is coupled to the top surface in the first portion. In some aspects, the techniques described herein relate to a heat exchange device, wherein the plurality of heat pipes includes six plurality of heat pipes. In some aspects, the techniques described herein relate to a heat exchange device, wherein the substrate portion of each plurality of heat pipes is coupled to the top surface in two groups of three plurality of heat pipes. Moreover, each two groups is arranged in a staggered pitch arrangement.

In some aspects, the techniques described herein relate to a heat exchange device, wherein each plurality of fins includes a perimeter portion and a chamber portion. The chamber portion includes a vapor chamber and the perimeter portion surrounds a perimeter of the chamber portion. In some aspects, the techniques described herein relate to a heat exchange device, wherein each plurality of fins further includes a plurality of transport through holes and the fin stack portion is respectively coupled to each plurality of fins through each plurality of transport through holes. Moreover, the chamber portion includes two chamber portions and the plurality of transport through holes is between each two chamber portions.

In some aspects, the techniques described herein relate to a heat exchange device, wherein the chamber portion includes a plurality of airflow through holes, whereby air flows through each plurality of airflow through holes. In some aspects, the techniques described herein relate to a heat exchange device, wherein the plurality of airflow through holes is arranged in a staggered pitch arrangement. In some aspects, the techniques described herein relate to a heat exchange device, wherein the plurality of airflow through holes includes a hexagonal shape.

In some aspects, the techniques described herein relate to a heat exchange device, wherein the plurality of fins includes fifteen plurality of fins. In some aspects, the techniques described herein relate to a heat exchange device, wherein each plurality of fins further includes a first perimeter side, a second perimeter side, at least a first spacer, and at least a second spacer. The first perimeter side is opposite the second perimeter side and the at least a first spacer is perpendicularly extending from a corner of the first perimeter side. The at least a second spacer is perpendicularly extending from a corner of the second perimeter side and the at least a first spacer and the at least a second spacer defining a spacer gap between each neighboring plurality of fins. In some aspects, the techniques described herein relate to a heat exchange device, wherein the at least a first spacer includes two at least a first spacer, and the at least a second spacer includes two at least a second spacer. A second at least a first spacer is perpendicularly extending from a corner of the first perimeter side opposing the at least a first spacer. The second at least a second spacer is perpendicularly extending from a corner of the second perimeter side opposing the at least a second spacer.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of heat exchange devices incorporating aspects of the presently disclosed principles are illustrated by way of example, and not by way of limitation.

FIG. 1A illustrates a perspective view of a heat exchange device, in accordance with various embodiments of the present disclosure.

FIG. 1B illustrates an alternative perspective view of the heat exchange device of FIG. 1A, in accordance with various embodiments of the present disclosure.

FIG. 1C illustrates another alternative perspective view of the heat exchange device of FIG. 1A, in accordance with various embodiments of the present disclosure.

FIG. 1D illustrates yet another alternative perspective view of the heat exchange device of FIG. 1A, in accordance with various embodiments of the present disclosure.

FIG. 1E illustrates further yet another perspective view of the heat exchange device of FIG. 1A, in accordance with various embodiments of the present disclosure.

FIG. 2 illustrates an exploded view of the heat exchange device of FIG. 1A, in accordance with various embodiments of the present disclosure.

### DETAILED DESCRIPTION

The following describes various principles related to components and assemblies for electronic devices cooling by way of reference to specific examples of heat exchange devices, including specific arrangements and examples of fin stacks, heat pipes and thermally conductive substrates embodying innovative concepts. More particularly, but not exclusively, such innovative principles are described in relation to selected examples of fin stack positioning in relation to thermally conductive substrates and coupling of heat pipes to the thermally conductive substrates, and well-known functions or constructions are not described in detail for purposes of succinctness and clarity. Nonetheless, one or more of the disclosed principles can be incorporated in various other embodiments of fin stack positioning in relation to thermally conductive substrates and coupling of heat pipes to the thermally conductive substrates to achieve any of a variety of desired outcomes, characteristics, and/or performance criteria.

Thus, fin stack positioning in relation to thermally conductive substrates and coupling of heat pipes to the thermally conductive substrates having attributes that are different from those specific examples discussed herein can embody one or more of the innovative principles, and can be used in applications not described herein in detail. Accordingly, embodiments of fin stack positioning in relation to thermally conductive substrates and coupling of heat pipes to the thermally conductive substrates not described herein in detail also fall within the scope of this disclosure, as will be appreciated by those of ordinary skill in the relevant art following a review of this disclosure.

Example embodiments as disclosed herein are directed to heat exchange devices that can be used in cooling systems to dissipate high heat loads. The heat exchange devices may be configured on a chassis, within a chassis, or as part of an electronics system that includes heat producing electronic components to be cooled. The heat exchange devices may be thermally coupled to an upper surface of a packaged integrated circuit, absorbing heat from the packaged integrated circuit and transporting the heat away via heat pipes coupled to a fin stack. The heat may be transported to an air plenum or to an outside of a chassis or electronics system via the fin stack, naturally or forced (e.g. one or more fans coupled to a back end of the fin stack via fasteners such as bolts, screws, etc.). The integrated circuit may include central processing units (CPUs), graphics processing units (GPUs), etc.

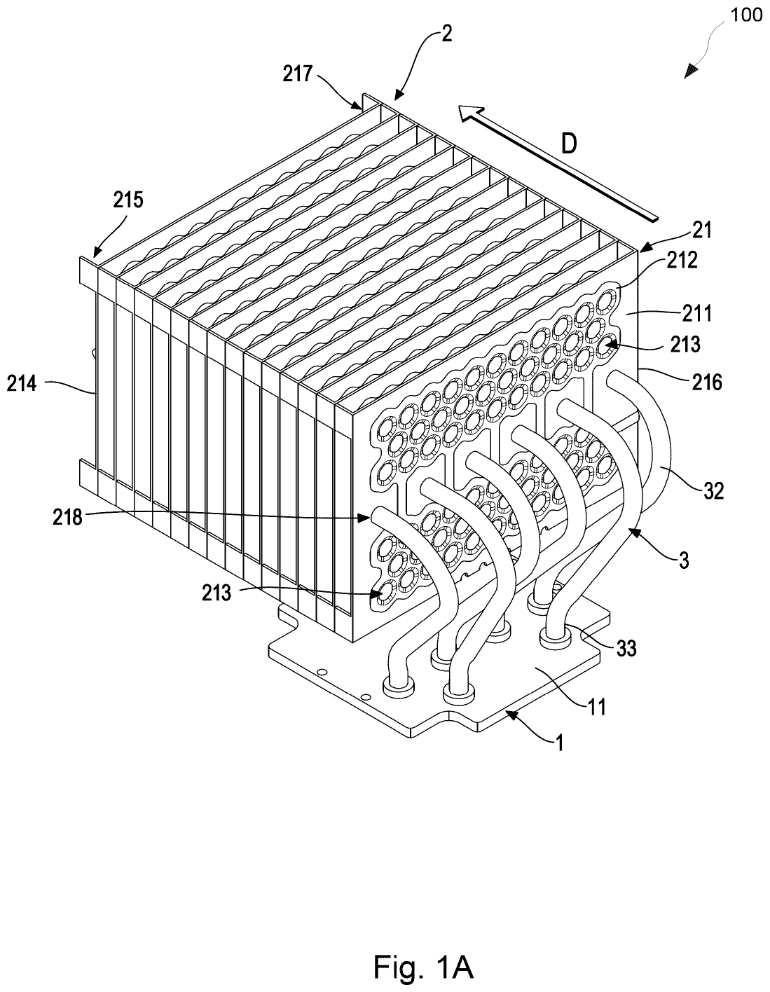

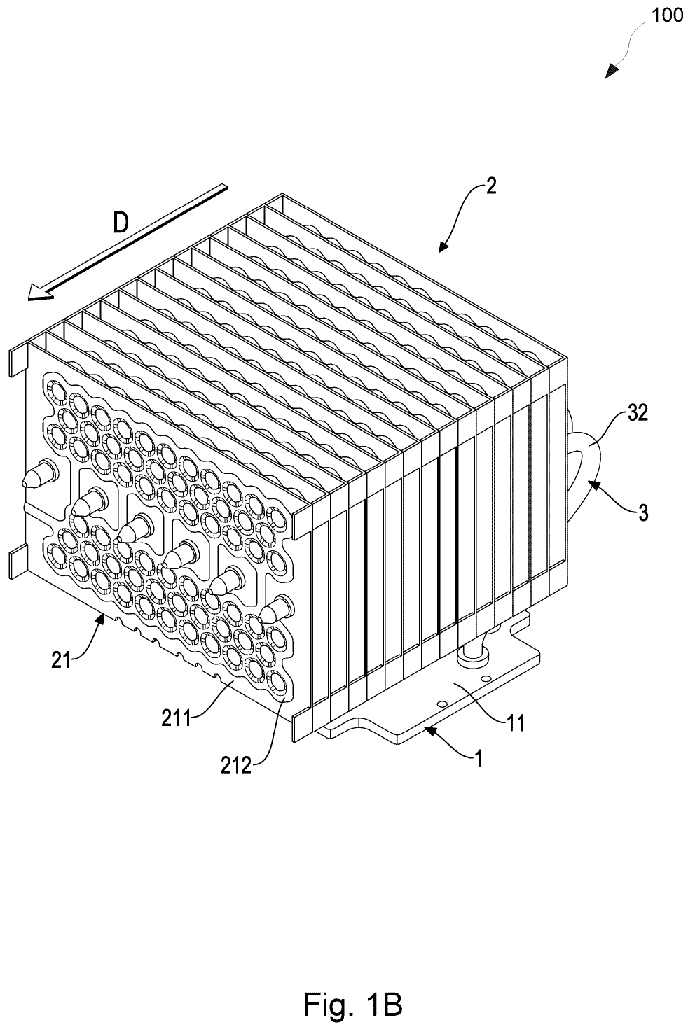

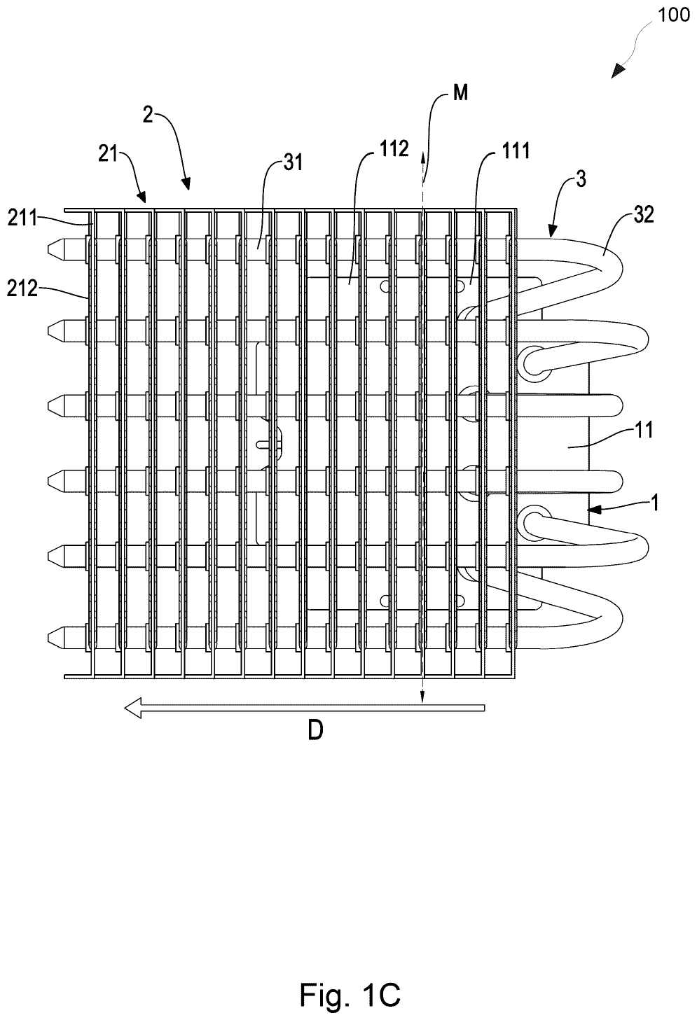

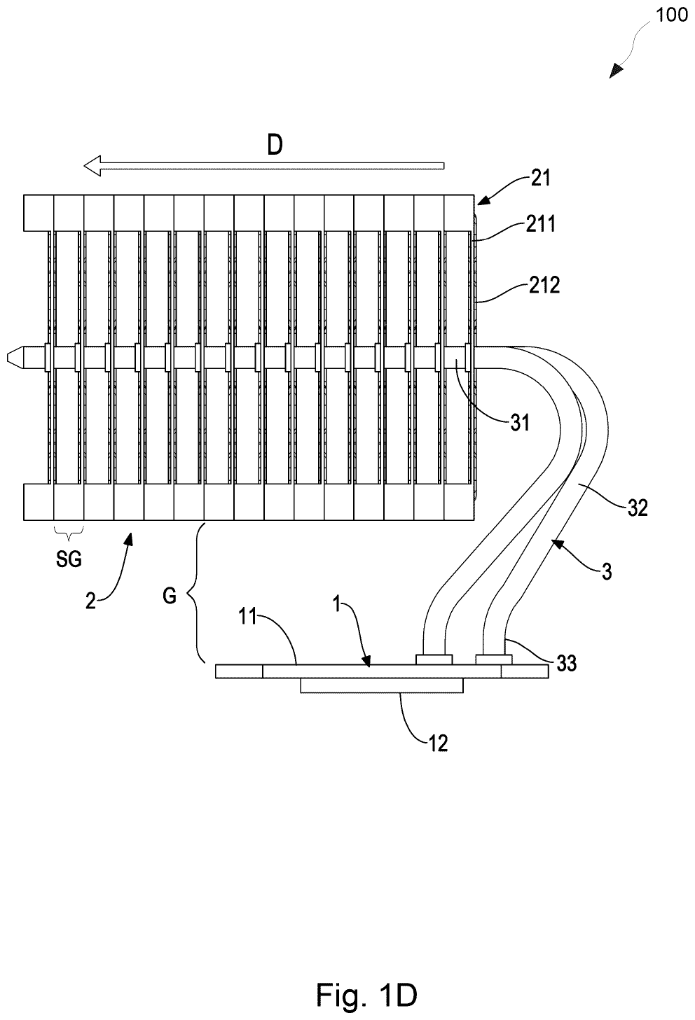

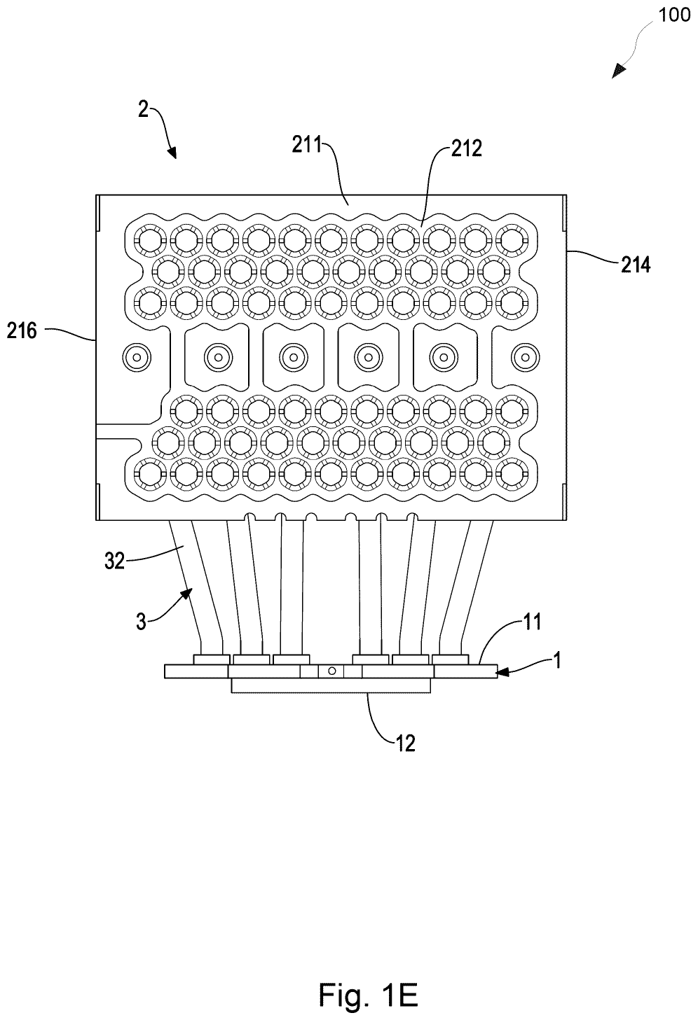

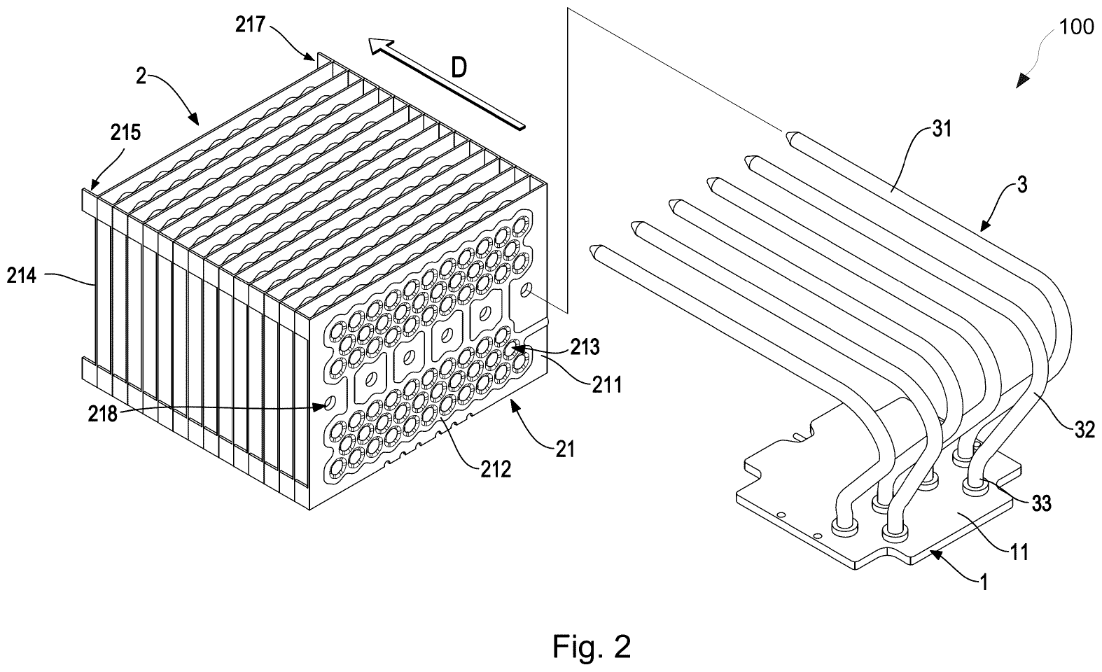

FIGS. 1A to 2 illustrate a heat exchange device 100, in accordance with various embodiments of the present disclosure. The heat exchange device 100 includes a fin stack 2, a plurality of heat pipes 3, and a thermally conductive substrate 1. The fin stack 2 includes a plurality of fins 21 defining a stacked direction D. The plurality of heat pipes 3 have a fin stack portion 31, a transportation portion 32, and a substrate portion 33. The transportation portion 32 is between the fin stack portion 31 and the substrate portion 33. The thermally conductive substrate 1 includes a top surface 11 and a bottom surface 12. The fin stack portion 31 is coupled to each plurality of fins 21 and the substrate portion 33 is coupled to the top surface 11. The bottom surface 12 is configured to couple to at least one packaged integrated circuit (not shown). The transportation portion 32 includes at least one bend defining a gap G between the fin stack 2 and the top surface 11. A direction of the stacked direction D is along a plane of the top surface 11. In some embodiments, the at least one bend includes two at least one bend, whereby each plurality of heat pipes 3 form an offset handle-like shape. The offset handle-like shape positions the fin stack 2 closer to the shaft of the substrate portion 33, distributing weight more evenly along the substrate portion 33.

In some embodiments, a plane of the fin stack 2 in the stacked direction D is different from the plane of the top surface 11 in the stacked direction D and the plane of the fin stack 2 is parallel to the plane of the top surface 11.

In some embodiments, the thermally conductive substrate 1 further includes a median M, a first portion 111, and a second portion 112. The median M defines the first portion 111 on one side and the second portion 112 on an opposite neighboring side. The substrate portion 33 is coupled to the top surface 11 in the first portion 111. In some embodiments, the plurality of heat pipes 3 includes six plurality of heat pipes 3. In some embodiments, the substrate portion 33 of each plurality of heat pipes 3 is coupled to the top surface 11 in two groups of three plurality of heat pipes 3. Moreover, each two groups is arranged in a staggered pitch arrangement.

In some embodiments, each plurality of fins 21 includes a perimeter portion 211 and a chamber portion 212. The chamber portion 212 includes a vapor chamber and the perimeter portion 211 surrounds a perimeter of the chamber portion 212. In some embodiments, the chamber portion 212 is further configured for phase-change of a cooling fluid therein. In some embodiments, the chamber portion 212 further includes wick microstructures (not shown) on inner surfaces of the chamber portion 212. In some embodiments, each plurality of fins 21 further includes a plurality of transport through holes 218 and the fin stack portion 31 is respectively coupled to each plurality of fins 21 through each plurality of transport through holes 218. Moreover, the chamber portion 212 includes two chamber portions 212 and the plurality of transport through holes 218 is between each two chamber portions 212.

In some embodiments, the chamber portion 212 includes a plurality of airflow through holes 213, whereby air flows through each plurality of airflow through holes 213. In some embodiments, the plurality of airflow through holes 213 is arranged in a staggered pitch arrangement. In some embodiments, the plurality of airflow through holes 213 includes a hexagonal shape. In some embodiments, the plurality of airflow through holes 213 includes different shapes, as examples, wavy shapes, spiral shapes, etc., defining less impeding chamber pathways.

In some embodiments, the bottom surface 12 is thermally coupled to the at least one packaged integrated circuit (not shown) transporting heat away from the at least one packaged integrated circuit. The substrate portion 33 of each plurality of heat pipes 3 is coupled to the top surface 11 of the thermally conductive substrate 1, transporting heat away from the thermally conductive substrate 1. The plurality of airflow through holes 213 of the chamber portion 212 of each plurality of fins 21 of the fin stack 2 is thermally coupled to the fin stack portion 31 of each plurality of heat pipes 3 via the plurality of transport through holes 218 of the perimeter portion 211, transporting heat away from each plurality of heat pipes 3. Passive two-phase heat transfer occurs in the chamber portion 212. One or more fans can be coupled to the fin stack 2, transporting heat to an air plenum or to an outside of a chassis or electronics system.

In some embodiments, the plurality of fins 21 includes fifteen plurality of fins 21. In some embodiments, each plurality of fins 21 further includes a first perimeter side 214, a second perimeter side 216, at least a first spacer 215, and at least a second spacer 217. The first perimeter side 214 is opposite the second perimeter side 216 and the at least a first spacer 215 is perpendicularly extending from a corner of the first perimeter side 214. The at least a second spacer 217 is perpendicularly extending from a corner of the second perimeter side 216 and the at least a first spacer 215 and the at least a second spacer 217 defining a spacer gap SG between each neighboring plurality of fins 21. In some embodiments, the at least a first spacer 215 includes two at least a first spacers 215, and the at least a second spacer 217 includes two at least a second spacers 217. A second at least a first spacer 215 is perpendicularly extending from a corner of the first perimeter side 214 opposing the at least a first spacer 215. The second at least a second spacer 217 is perpendicularly extending from a corner of the second perimeter side 216 opposing the at least a second spacer 217. In some embodiments, each plurality of fins 21 is further coupled parallelly to neighboring plurality of fins 21 via the at least a first spacer 215 and the at least a second spacer 217.

Longitudinal axis footprint of heat exchange devices 100 of the present disclosure is decreased and effective heat dissipation and stable structural integrity are provided. The offset handle-like shape of each plurality of heat pipes 3 distributes weight of the fin stack 2 more evenly along the substrate portion 33, improving structural stability. Moreover, structural stability is further improved via the staggered pitch arrangement of the substrate portion 33 of the two groups of three plurality of heat pipes 3. Furthermore, the plane of the fin stack 2 in the stacked direction D is different from the plane of the top surface 11 in the stacked direction D, the plane of the fin stack 2 is parallel to the plane of the top surface 11, and a plane of each plurality of fins 21 can be perpendicular to the plane of the top surface 11. Thus, the gap G between the fin stack 2 and the top surface 11 formed by the offset handle-like shape of each plurality of heat pipes 3 decreases a longitudinal axis footprint of the heat exchange devices 100 of the present discloser. The vapor chamber, wick microstructures, plurality of airflow through holes 213 of the chamber portion 212, and each plurality of fins 21 being coupled parallelly to neighboring plurality of fins 21 via the at least a first spacer 215 and the at least a second spacer 217 enhance heat dissipation of the fin stack 2. Thus, a heat exchange device with compact footprint and high thermal conductivity is provided.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A heat exchange device, comprising:
a fin stack including a plurality of fins, the plurality of fins defining a stacked direction;
a plurality of heat pipes having a fin stack portion, a transportation portion, and a substrate portion, the transportation portion between the fin stack portion and the substrate portion, the fin stack portion coupled to each plurality of fins; and
a thermally conductive substrate including a top surface and a bottom surface, the substrate portion coupled to the top surface, the bottom surface configured to couple to at least one packaged integrated circuit,
wherein the transportation portion includes at least one bend, the at least one bend defining a gap between the fin stack and the top surface, and
wherein a direction of the stacked direction is along a plane of the top surface.

2. The heat exchange device of claim 1, wherein the thermally conductive substrate further includes a median, a first portion, and a second portion, the median defining the first portion on one side and the second portion on an opposite neighboring side, the substrate portion coupled to the top surface in the first portion.

3. The heat exchange device of claim 1, wherein the plurality of heat pipes comprises six plurality of heat pipes.

4. The heat exchange device of claim 3, wherein the substrate portion of each plurality of heat pipes is coupled to the top surface in two groups of three plurality of heat pipes, each two groups arranged in a staggered pitch arrangement.

5. The heat exchange device of claim 1, wherein the plurality of fins comprises fifteen plurality of fins.

6. The heat exchange device of claim 1, wherein each plurality of fins includes a perimeter portion and a chamber portion, the chamber portion including a vapor chamber, the perimeter portion surrounding a perimeter of the chamber portion.

7. The heat exchange device of claim 6, wherein each plurality of fins further includes a plurality of transport through holes, the fin stack portion respectively coupled to each plurality of fins through each plurality of transport through holes, and wherein the chamber portion comprises two chamber portions, the plurality of transport through holes between each two chamber portions.

8. The heat exchange device of claim 6, wherein the chamber portion includes a plurality of airflow through holes, whereby air flows through each plurality of airflow through holes.

9. The heat exchange device of claim 8, wherein the plurality of airflow through holes is arranged in a staggered pitch arrangement.

10. The heat exchange device of claim 8, wherein the plurality of airflow through holes includes a hexagonal shape.

11. The heat exchange device of claim 8, wherein each plurality of fins further includes a first perimeter side, a second perimeter side, at least a first spacer, and at least a second spacer, the first perimeter side opposite the second perimeter side, the at least a first spacer perpendicularly extending from a corner of the first perimeter side, the at least a second spacer perpendicularly extending from a corner of the second perimeter side, the at least a first spacer and the at least a second spacer defining a spacer gap between each neighboring plurality of fins.

12. The heat exchange device of claim 11, wherein the at least a first spacer comprises two at least a first spacer, and the at least a second spacer comprises two at least a second spacer, a second at least a first spacer perpendicularly extending from a corner of the first perimeter side opposing the at least a first spacer, a second at least a second spacer perpendicularly extending from a corner of the second perimeter side opposing the at least a second spacer.
